(19) United States
(12) Patent Application Publication
(10) Pub. No.: US 2024/0268081 A1
(43) Pub. Date: Aug. 8, 2024

(54) COMPOSITE HEAT DISSIPATION DEVICE

(71) Applicant: TAIWAN MICROLOOPS CORP., New Taipei City (TW)

(72) Inventors: Chun-Hung LIN, New Taipei City (TW); Han-Lin CHEN, New Taipei City (TW)

(21) Appl. No.: 18/127,013

(22) Filed: Mar. 28, 2023

(30) Foreign Application Priority Data
Feb. 2, 2023 (TW) 112103695

(51) Int. Cl. H05K 7/20

(52) U.S. Cl. CPC H05K 7/20563; H05K 7/20145; H05K 7/20154; H05K 7/20409

(57) ABSTRACT

A composite heat dissipation device includes a base, a cover, a first fan, and a second fan. The cover covers the base to form a first heat dissipation area and a second heat dissipation area. The cover is provided with a first air inlet and a first air outlet communicating with the first air inlet. The cover is provided with a second air inlet, and a second air outlet and a third air outlet communicating with the second air inlet. A first fan is corresponding to the first air inlet and the first air outlet. A second fan is corresponding to the second air inlet, the second and the third air outlets. The first air outlet is opposite to the second air outlet, and the third air outlet is adjacent to the second air outlet, the air outlets do not interfere with each other, and heat dissipation performance is improved.

### BACKGROUND OF THE DISCLOSURE

### Technical Field

The present disclosure relates to a technical field of a heat dissipation device, and in particular, to a composite heat dissipation device.

### Description of Related Art

Due to the improvement of 3D graphics software and its imaging function, graphics chips of the graphics cards for processing images have greatly improved its compute capability, which causes problems of heat rise of processors and problems of heat dissipation.

In related-art heat dissipation designs for the graphics cards, there are still many graphics cards that dissipate heat by means of air cooling, aside from liquid cooling. It is common practice to combine heat sinks and cooling fans. However, such combination of components often have limited heat dissipation efficiency for waste heat generated by electronic heat sources under the influence of the surrounding environment or due to the mutual interference between airflows. Therefore, the present application aims to solve the aforementioned technical problems.

In light of the above, the inventor of the present disclosure has devoted himself to doing research and studying scientific principles so as to solve the above problem of related-art techniques.

### SUMMARY OF THE DISCLOSURE

It is an objective of the present disclosure to provide a composite heat dissipation device with air outlets provided in a scattered arrangement, so that airflows do not interfere with each other, thereby improving heat dissipation performance.

Accordingly, the present disclosure provides a composite heat dissipation device, including a base, a cover, a first fan, and a second fan. The cover covers the base. A first heat dissipation area and a second heat dissipation area are arranged between the base and the cover. In the first heat dissipation area, the cover is provided with a first air inlet and a first air outlet communicating with the first air inlet. In the second heat dissipation area, the cover is provided with a second air inlet, a second air outlet, and a third air outlet, and the second air outlet and the third air outlet communicate with the second air inlet. The first fan is disposed on the base and arranged corresponding to the first air inlet and the first air outlet. The second fan is disposed on the base and arranged corresponding to the second air inlet, the second air outlet, and the third air outlet. The first air outlet and the second air outlet are arranged at two sides of the cover opposite to each other, and the third air outlet is arranged adjacent to the second air outlet.

The present disclosure provides the following function. In the second heat dissipation area, the number of the air outlets is greater than the number of the air inlets. Therefore, waste heat generated by the second heat dissipation member is quickly and sufficiently discharged to the outside of the cover. Further, a partition of the cover is used to block air circulation between the first heat dissipation area and the second heat dissipation area. An airflow direction in the second heat dissipation channel is opposite to an airflow direction in the first heat dissipation channel, so that waste heat generated by each electronic heat source may spread out to be discharged.

### BRIEF DESCRIPTION OF THE DRAWINGS

FIG. 1 is an appearance view illustrating a composite heat dissipation device of the present disclosure.

FIG. 2 is a perspective view illustrating the composite heat dissipation device of the present disclosure.

FIG. 3 is an appearance view of the present disclosure, illustrating the composite heat dissipation device observed from another direction.

FIG. 4 is a cross-sectional view illustrating the composite heat dissipation device of the present disclosure.

FIG. 5 is a cross-sectional view, taken along another direction, illustrating the composite heat dissipation device of the present disclosure.

FIG. 6 is an appearance view illustrating the present disclosure used on a graphics card.

FIG. 7 is a first cross-sectional view illustrating the present disclosure used on the graphics card.

FIG. 8 is a second cross-sectional view illustrating the present disclosure used on the graphics card.

FIG. 9 is a cross-sectional view illustrating the present disclosure used on the graphics card according to another embodiment.

### DETAILED DESCRIPTION

The technical content of the present disclosure is described in detail below with reference to the accompanying drawings. The accompanying drawings are only for reference and illustrative purposes, and are not intended to limit the present disclosure.

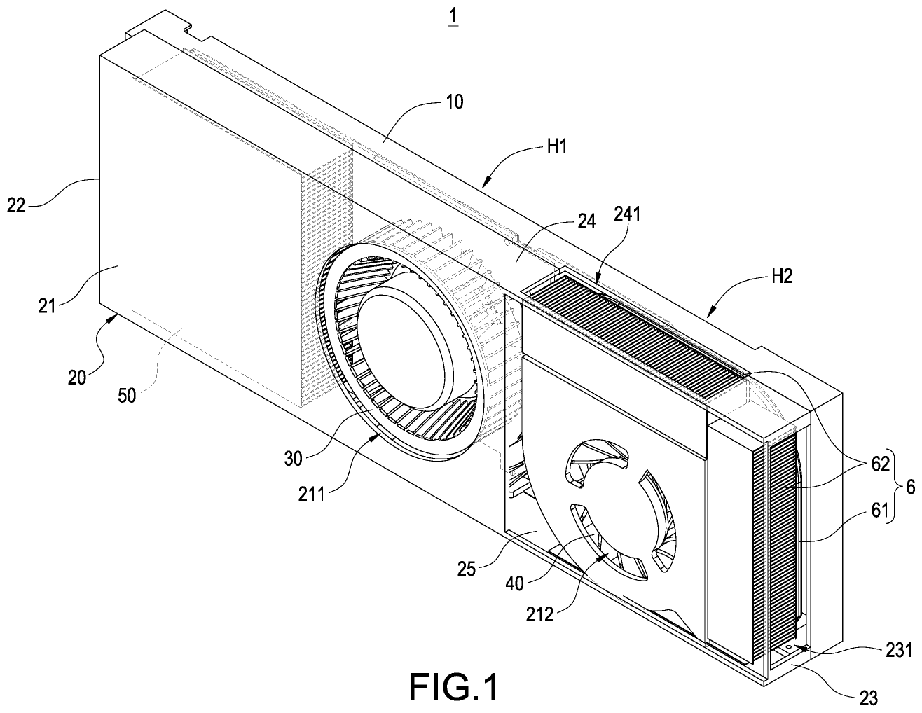

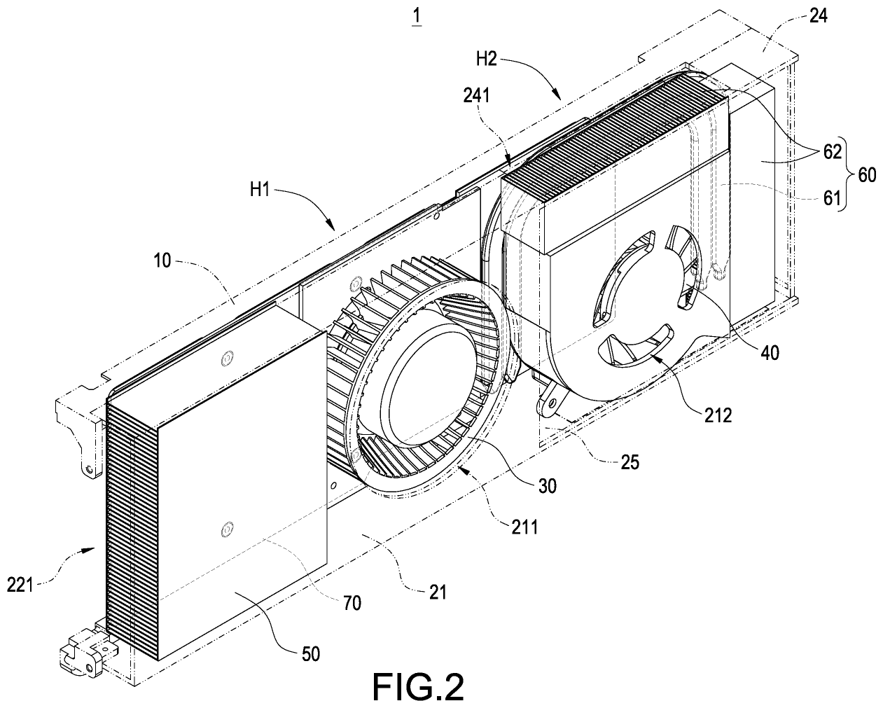

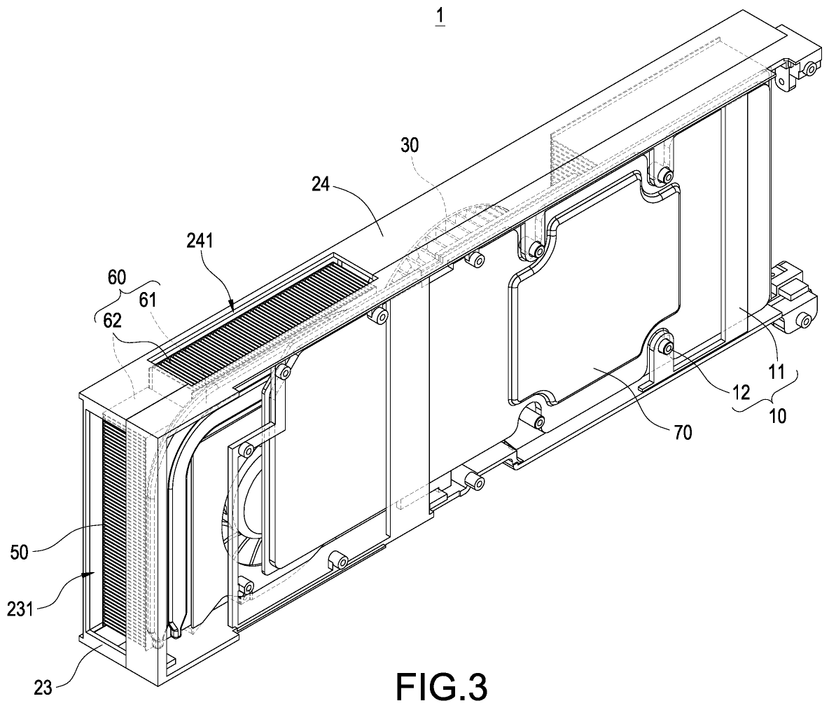

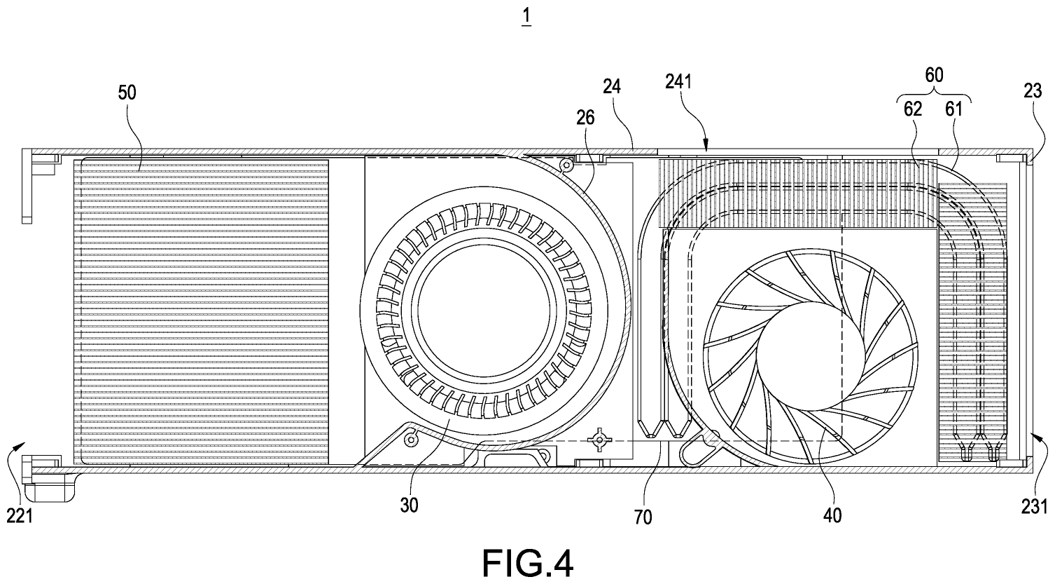

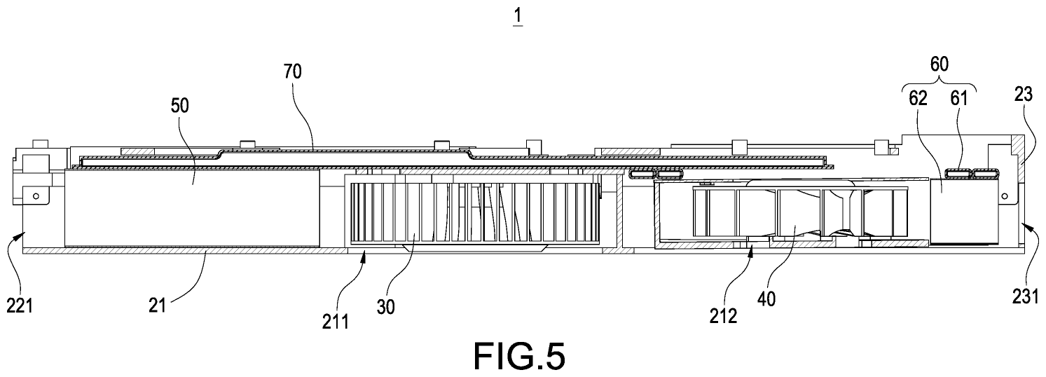

Referring to FIG. 1 to FIG. 5, the present disclosure provides a composite heat dissipation device. The composite heat dissipation device 1 includes a base 10, a cover 20, a first fan 30, and a second fan 40.

The base 10 is substantially rectangular-shaped, which includes a plurality of support rods 11 and a plurality of studs 12. The support rods 11 are arranged at intervals and arranged in a horizontal direction and in a vertical direction. Some of the support rods 11 are provided with the studs 12 to be fastened to locking elements such as screws by treaded connection.

The cover 20 covers the base 10 and is arranged on one side of the base 10. A first heat dissipation area H1 and a second heat dissipation area H2 are arranged between the base 10 and the cover 20.

In one embodiment, the cover 20 may be made of a metal material and has a rectangular shape. The cover 20 mainly includes a panel 21, a left side plate 22, a right side plate 23, an upper side plate 24, and a lower side board 25, and the left side plate 22, the right side plate 23, the upper side plate 24, and the lower side board 25 are perpendicularly extended from the panel 21. The left side plate 22 is disposed opposite to the right side plate 23. The upper side plate 24 is disposed adjacent to the plate side plate 23.

A first air inlet 211 is defined on the panel 21 of the cover 20 in the first heat dissipation area H1. A first air outlet 221 communicating with the first air inlet 211 is defined on the left side plate 22 of the cover 20. A second air inlet 212 is defined on the panel 21 of the cover 20 in the second heat dissipation area H2. A second air outlet 231 communicating with the second air inlet 212 is defined on the right side plate 23 of the cover 20. A third air outlet 241 communicating with the second air inlet 212 is defined on the upper side plate 24 of the cover 20.

In one embodiment, the cover 20 further includes a partition 26. The partition 26 is disposed between the first heat dissipation area H1 and the second heat dissipation area H2, so as to block air circulation between the first heat dissipation area H1 and the second heat dissipation area H2.

The first fan 30 is a centrifugal fan disposed on the base 10 and arranged corresponding to the first air inlet 211 and the first air outlet 221. An impeller of the first fan 30 may be made of a metal material.

The second fan 40 is also a centrifugal fan. The second fan 40 is disposed on the base 10 and arranged corresponding to the second air inlet 212, the second air outlet 231, and the third air outlet 241. An impeller of the second fan 40 may be made of a metal material.

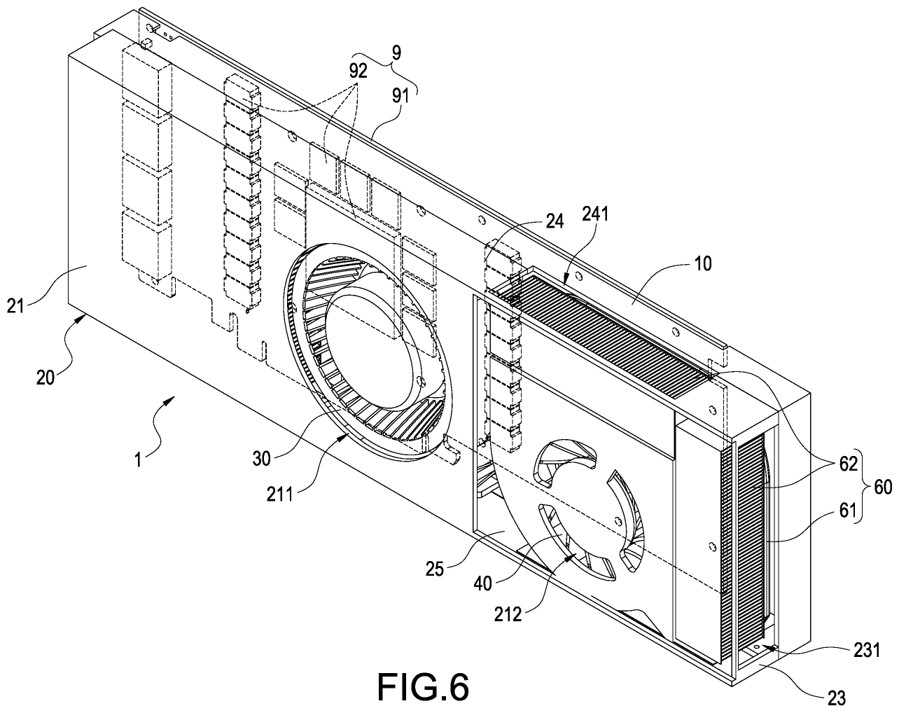

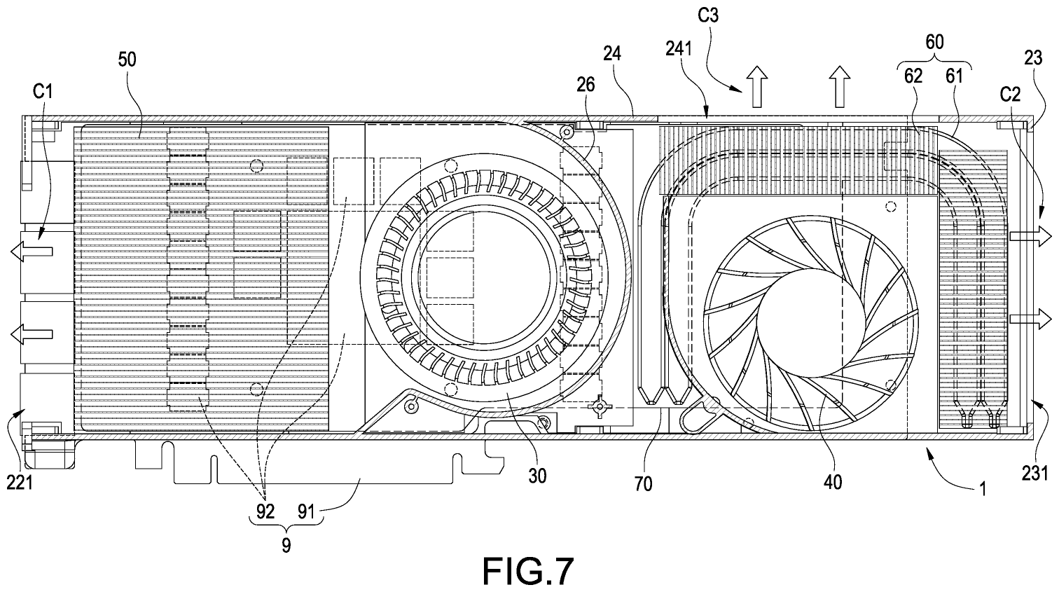

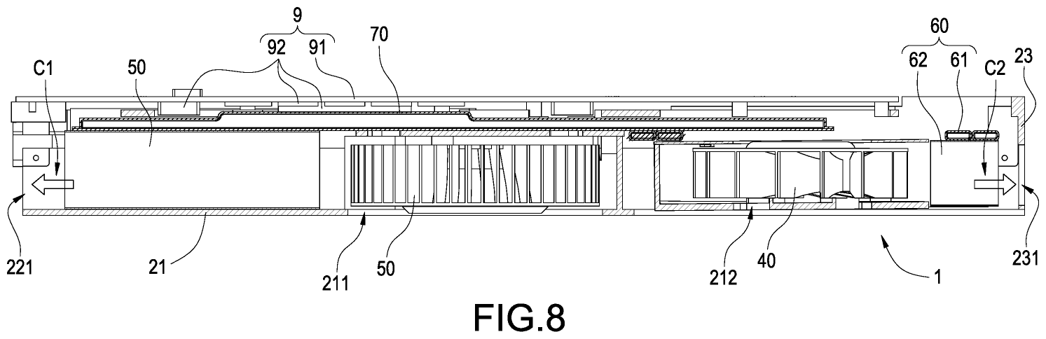

In one embodiment, the first heat dissipation area H1 includes a first heat dissipation channel C1 (as shown in FIG. 6 to FIG. 8), the first heat dissipation channel C1 is defined as air entering into the cover 20 from the first air inlet 211 and being discharged to outside of the cover 20 from the first air outlet 221 through the first fan 30.

In one embodiment, the composite heat dissipation device 1 of the present disclosure further includes a first heat dissipation member 50 arranged in the first heat dissipation channel C1 and disposed between the first fan 30 and the first air outlet 221. The first heat dissipation member 50 may be a heat dissipation fin set.

In one embodiment, the second heat dissipation area H2 includes a second heat dissipation channel C2 (as shown in FIG. 6 to FIG. 8), the second heat dissipation channel C2 is defined as the air entering into the cover 20 from the second air inlet 212 and being discharged to outside of the cover 20 from the second air outlet 231 through the second fan 40. The second heat dissipation area H2 also includes a third heat dissipation channel C3 (as shown in FIG. 6 to FIG. 8), the third heat dissipation channel C3 is defined as the air being discharged to outside of the cover 20 from the third air outlet 241 through the second fan 40.

In one embodiment, the composite heat dissipation device 1 of the present disclosure further includes a second heat dissipation member 60. The second heat dissipation member 60 is disposed in the second heat dissipation channel C2 and the third heat dissipation channel C3. The second heat dissipation member 60 includes a heat pipe 61 and two heat dissipation fin sets 62, the heat pipe 61 is U-shaped and arranged around an outer periphery of the second fan 40. One of the heat dissipation fin sets 62 is attached to the heat pipe 61 and disposed between the second fan 40 and the second air outlet 231. The other one of the heat dissipation fin sets 62 is attached to the heat pipe 61 and disposed between the second fan 40 and the third air outlet 241.

In one embodiment, the composite heat dissipation device 1 of the present disclosure further includes a vapor chamber (VC) 70. The vapor chamber 70 is disposed on the base 10 and is in thermal contact with the first heat dissipation member 50 and the second heat dissipation member 60.

Referring to FIGS. 6 to 8, the composite heat dissipation device 1 of the present disclosure may be used for heat dissipation of a graphics card 9. The graphics card 9 mainly includes a circuit board 91 and a plurality of electronic heat sources 92 (e.g., GPU and DRAM) arranged on the circuit board 91. Each electronic heat source 92 is attached to the vapor chamber 70. Waste heat generated by each electronic heat source 92 after operation is first transferred to the vapor chamber 70. Then, part of the waste heat is transferred to the first heat dissipation member 50. Other part of the waste heat is transferred to the heat pipe 61 of the second heat dissipation member 60 and is transferred to each heat dissipation fin set 62 through the heat pipe 61. Through the operation of the first fan 30, the external air is drawn from the first air inlet 211 into the cover 20 and discharged to outside of the cover 20 from the first air outlet 221. Furthermore, through the operation of the second fan 40, the external air is drawn into the cover 20 from the second air inlet 212, part of the air is discharged to outside of the cover 20 from the second air outlet 231, and other part of the air is discharged to outside of the cover 20 from the third air outlet 241. An airflow direction in the second heat dissipation channel C2 is opposite to an airflow direction in the first heat dissipation channel C1, and an airflow direction in the third heat dissipation channel C3 is perpendicular to the airflow direction in the second heat dissipation channel C2. The first air outlet 221, the second air outlet 231, and the third air outlet 241 are located in different directions of the cover 20, so that the delivered airflows do not interfere with each other, thereby improving heat dissipation performance.

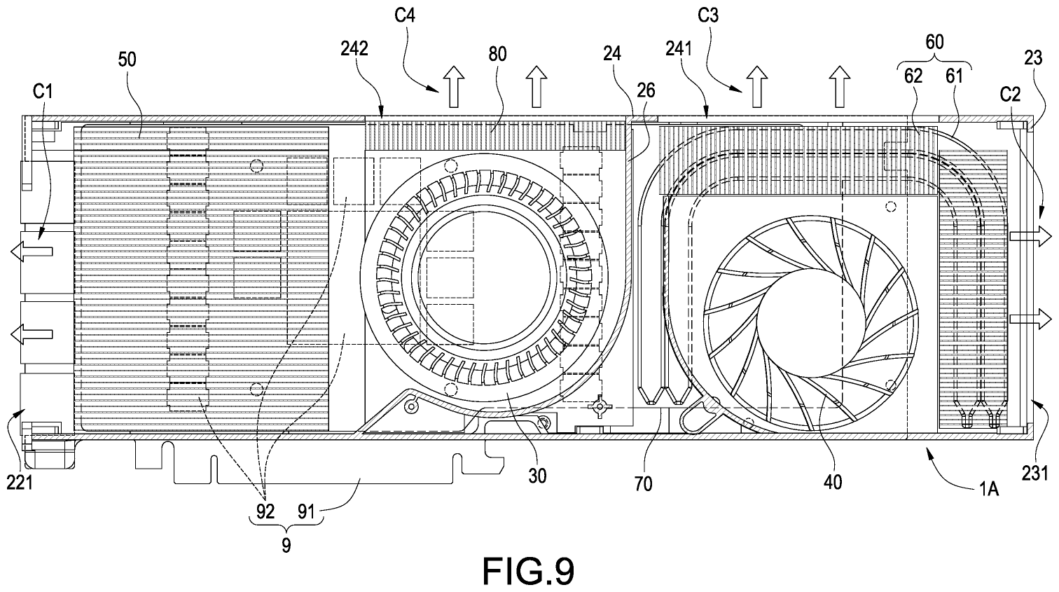

Please refer to FIG. 9. In the composite heat dissipation device 1A of the present embodiment, a fourth air outlet 242 communicating with the first air inlet 211 is defined on the upper side plate 24 of the cover 20 in the first heat dissipation area H1. The heat dissipation area H1 includes a fourth heat dissipation channel C4, the fourth heat dissipation channel C4 is defined as the air entering into the cover 20 from the first air inlet 211 and being discharged to outside of the cover from the fourth air outlet 242 through the first fan 30. An airflow direction in the fourth heat dissipation channel C4 is perpendicular to the airflow direction in the first heat dissipation channel C1 and parallel to the airflow direction in the third heat dissipation channel C3. Moreover, the composite heat dissipation device 1A also includes a third heat dissipation member 80. The third heat dissipation member 80 is arranged in the fourth heat dissipation channel C4 and is disposed between the first fan 30 and the fourth air outlet 242. The third heat dissipation member 80 is also a heat dissipation fin set and is in thermal contact with the vapor chamber 70, so as to dissipate the waste heat.

While this disclosure has been described by means of specific embodiments, numerous modifications and variations may be made thereto by those skilled in the art without departing from the scope and spirit of this disclosure set forth in the claims.

What is claimed is:

1. A composite heat dissipation device, comprising:
a base;
a cover, covering the base, comprising a first heat dissipation area and a second heat dissipation area arranged between the base and the cover, a first air inlet and a first air outlet defined on the first heat dissipation area, the first air outlet communicating with the first air inlet, a second air inlet, a second air outlet, and a third air outlet defined on the second heat dissipation area, and the second air outlet and the third air outlet communicating with the second air inlet;
a first fan, disposed on the base and arranged corresponding to the first air inlet and the first air outlet; and
a second fan, disposed on the base and arranged corresponding to the second air inlet, the second air outlet, and the third air outlet;
wherein the first air outlet and the second air outlet are arranged at two sides of the cover opposite to each other, and the third air outlet is arranged adjacent to the second air outlet.

2. The composite heat dissipation device according to claim 1, wherein the first heat dissipation area comprises a first heat dissipation channel, and the first heat dissipation channel is defined as an air entering into the cover from the first air inlet and being discharged to outside of the cover from the first air outlet through the first fan.

3. The composite heat dissipation device according to claim 2, further comprising a first heat dissipation member arranged in the first heat dissipation channel, and disposed between the first fan and the first air outlet.

4. The composite heat dissipation device according to claim 1, wherein the second heat dissipation area comprises a second heat dissipation channel and a third heat dissipation channel, the second heat dissipation channel is defined as an air entering into the cover from the second air inlet and being discharged to outside of the cover from the second air outlet through the second fan, and the third heat dissipation channel is defined as the air being discharged to outside of the cover from the third air outlet through the second fan.

5. The composite heat dissipation device according to claim 4, further comprising a second heat dissipation member disposed in the second heat dissipation channel and the third heat dissipation channel.

6. The composite heat dissipation device according to claim 5, wherein the second heat dissipation member comprises a heat pipe and two heat dissipation fin sets, the heat pipe is U-shaped and arranged around an outer periphery of the second fan, one of the heat dissipation fin sets is attached to the heat pipe and disposed between the second fan and the second air outlet, and another one of the heat dissipation fin sets is attached to the heat pipe and disposed between the second fan and the third air outlet.

7. The composite heat dissipation device according to claim 1, wherein the cover comprises a partition disposed between the first heat dissipation area and the second heat dissipation area to block an air circulation between the first heat dissipation area and the second heat dissipation area.

8. The composite heat dissipation device according to claim 1, wherein the cover comprises a panel, a left side plate, a right side plate, and an upper side plate, the left side plate, the right side plate, and the upper side plate are perpendicularly extended from the panel, the left side plate and the right side plate are arranged opposite to each other, the upper side plate and the right side plate are arranged adjacent to each other, the first air inlet and the second air inlet are arranged on the panel, the first air outlet is arranged on the left side plate, the second air outlet is arranged on the right side plate, and the third air outlet is arranged on the upper side plate.

9. The composite heat dissipation device according to claim 1, wherein the first heat dissipation area comprises a first heat dissipation channel, the first heat dissipation channel is defined as an air entering into the cover from the first air inlet and being discharged to outside of the cover from the first air outlet through the first fan, the second heat dissipation area comprises a second heat dissipation channel, the second heat dissipation channel is defined as the air entering into the cover from the second air inlet and being discharged to outside of the cover from the second air outlet through the second fan, and an airflow direction in the second heat dissipation channel is opposite to an airflow direction in the first heat dissipation channel.

10. The composite heat dissipation device according to claim 9, wherein the cover comprises a fourth air outlet defined on the first heat dissipation area and communicating with the first air inlet, the first heat dissipation area further comprises a fourth heat dissipation channel, the fourth heat dissipation channel is defined as the air being discharged to outside of the cover from the fourth air outlet through the first fan, and an airflow direction in the fourth heat dissipation channel is perpendicular to the airflow direction in the first heat dissipation channel.

11. The composite heat dissipation device according to claim 10, wherein the second heat dissipation area further comprises a third heat dissipation channel, the third heat dissipation channel is defined as the air being discharged to outside of the cover from the third air outlet through the second fan, an airflow direction in the third heat dissipation channel is perpendicular to the airflow direction in the second heat dissipation channel, and the airflow direction in the fourth heat dissipation channel is parallel to the airflow direction in the third heat dissipation channel.

12. The composite heat dissipation device according to claim 1, further comprising a first heat dissipation member, a second heat dissipation member, a third heat dissipation member, and a vapor chamber, wherein the first heat dissipation member and the third heat dissipation member are disposed in the first heat dissipation area, the second heat dissipation member is disposed in the second heat dissipation area, and the vapor chamber is disposed on the base and is in thermal contact with the first heat dissipation member, the second heat dissipation member, and the third heat dissipation member.
